(19) United States
(12) Patent Application Publication
(10) Pub. No.: US 2024/0421089 A1
(43) Pub. Date: Dec. 19, 2024

(54) SEMICONDUCTOR INTEGRATED CIRCUIT DEVICE

(71) Applicant: Socionext Inc., Kanagawa (JP)

(72) Inventor: Yoshiki ISHIGAKI, Yokohama-shi (JP)

(21) Appl. No.: 18/819,600

(22) Filed: Aug. 29, 2024

Related U.S. Application Data
(63) Continuation of application No. PCT/JP2022/009198, filed on Mar. 3, 2022.

(51) Int. Cl. H01L 23/528; H01L 23/00; H01L 23/48; H01L 25/065

(52) U.S. Cl. CPC H01L 23/5286; H01L 23/481; H01L 25/0657; H01L 24/08; H01L 24/16; H01L 2224/08146; H01L 2224/16146; H01L 2225/06527; H01L 2225/06544

(57) ABSTRACT

A first semiconductor chip includes a pad provided on a wiring layer and connected to a power supply for supplying a power supply voltage VSS, a power switch circuit provided between a VDD line and a VDDV line, a buried power supply line formed in a buried power supply wiring layer and connected to the power supply for supplying the power supply voltage VSS, and a via connected to the pad connected to the power supply for supplying the power supply voltage VSS and provided so as to penetrate a substrate and a wiring layer. A second semiconductor chip includes a line connected to the buried power supply line and the via.

### CROSS-REFERENCE TO RELATED APPLICATIONS

This is a continuation of International Application No. PCT/JP2022/009198 filed on Mar. 3, 2022. The entire disclosures of these applications are incorporated by reference herein.

### BACKGROUND

The present disclosure relates to a semiconductor integrated circuit device including semiconductor chips stacked on each other.

Semiconductor integrated circuits need to be designed more carefully about a power supply voltage drop (IR-Drop) and power supply noise due to higher integration and lower voltage associated with miniaturization. For this reason, it is important to design a power delivery network (PDN) for supplying a power supply voltage to the semiconductor integrated circuit.

A technique has been widely employed, in which the semiconductor integrated circuit is provided with a power switch for power consumption reduction and the power switch is turned ON/OFF according to system operation to reduce power consumption.

International Patent Publication No. WO 2020/065916 discloses a semiconductor device configured such that a power switch is provided for a first semiconductor chip of stacked semiconductor chips and a power supply potential (power supply voltage) is supplied to the power switch from a second semiconductor chip bonded to the back surface of the first semiconductor chip and including a power supply line.

### SUMMARY

In the International Patent Publication No. WO 2020/065916, the power supply voltage is supplied from a pad as an external terminal provided below the second semiconductor chip. This power supply voltage is supplied to the power switch of the first semiconductor chip through the power supply line of the second semiconductor chip.

In general, when a large-scale semiconductor integrated circuit device is designed, many circuits called intellectual property (IP) cores, which are grouped in units of specific functions, are used. Of these IP cores, an IP core called hard macro includes a layout structure in provided data, and the layout structure cannot be modified. In this case, if it is defined that the pad as the external terminal for the hard macro is provided on the first semiconductor chip, not only the external terminal below the second semiconductor chip but also the external terminal above the first semiconductor chip need to be provided in order to supply the power supply voltage in the structure as described in the International Patent Publication No. WO 2020/065916. For this reason, it is difficult to design the semiconductor integrated circuit device, and a cost increases.

The present disclosure is intended to provide a semiconductor integrated circuit device applicable to a case where it is defined that an external terminal is provided on a first semiconductor chip.

A first aspect of the present disclosure is directed to a semiconductor integrated circuit device including a first semiconductor chip and a second semiconductor chip. The back surface of the first semiconductor chip and the main surface of the second semiconductor chip being arranged so as to face each other. The first semiconductor chip includes a first terminal provided on a main surface and connected to a first power supply for supplying a first power supply voltage, a second terminal provided on the main surface and connected to a second power supply for supplying a second power supply voltage different from the first power supply voltage, a power switch circuit provided between the first power supply and a third power supply for supplying a third power supply voltage different from the first power supply voltage and the second power supply voltage to control connection and disconnection between the first power supply and the third power supply, a first buried power supply line formed in a buried power supply wiring layer and connected to the first power supply, a second buried power supply line formed in the buried power supply wiring layer and connected to the second power supply, and a first via connected to the first terminal and provided so as to penetrate from the main surface to the back surface. The second semiconductor chip includes a first line connected to the first buried power supply line and the first via.

According to the present disclosure, the first terminal connected to the first power supply for supplying the first power supply voltage is provided on the main surface of the first semiconductor chip. The first terminal is connected to the power switch circuit through the first via penetrating the first semiconductor chip from the main surface to the back surface, the first line of the second semiconductor chip, and the first buried power supply line of the first semiconductor chip. With this configuration, the first power supply voltage can be supplied to the power switch circuit from the first terminal provided on the main surface of the first semiconductor chip; therefore, the present device can be applied even to the case where providing of an external terminal on the first semiconductor chip is defined.

A second aspect of the present disclosure is directed to a semiconductor integrated circuit device including a first semiconductor chip and a second semiconductor chip, wherein the back surface of the first semiconductor chip and the main surface of the second semiconductor chip is arranged so as to face each other. The first semiconductor chip includes a first terminal provided on the main surface and connected to a first power supply for supplying a first power supply voltage, a second terminal provided on the main surface and connected to a second power supply for supplying a second power supply voltage different from the first power supply voltage, a power switch circuit provided between the first power supply and a third power supply for supplying a third voltage different from the first voltage and the second voltage to control connection and disconnection between the first power supply and the third power supply, a first buried power supply line formed in a buried power supply wiring layer and connected to the first power supply, a second buried power supply line formed in the buried power supply wiring layer and connected to the second power supply, and a first line formed in a first wiring layer above the buried power supply wiring layer and connected to the first terminal and the first buried power supply line. The second semiconductor chip includes a second line connected to the first buried power supply line.

According to the present disclosure, the first terminal connected to the first power supply for supplying the first power supply voltage is provided on the main surface of the first semiconductor chip. The first terminal is connected to the power switch circuit through the first line of the first wiring layer and the first buried power supply line of the buried power supply wiring layer in the first semiconductor chip. With this configuration, the first power supply voltage can be supplied to the power switch circuit from the first terminal provided on the main surface of the first semiconductor chip; therefore, the present device can be applied even to the case where providing of an external terminal on the first semiconductor chip is defined.

A third aspect of the present disclosure is directed to a semiconductor integrated circuit device including a first semiconductor chip and a second semiconductor chip, wherein the back surface of the first semiconductor chip and the main surface of the second semiconductor chip is arranged so as to face each other. The first semiconductor chip includes a first terminal provided on the main surface and connected to a first power supply for supplying a first power supply voltage, a second terminal provided on the main surface and connected to a second power supply for supplying a second power supply voltage different from the first power supply voltage, a power switch circuit provided between the first power supply and a third power supply for supplying a third voltage different from the first voltage and second voltage to control connection and disconnection between the first power supply and the third power supply, a first buried power supply line formed in a buried power supply wiring layer and connected to the first power supply, a second buried power supply line formed in the buried power supply wiring layer and connected to the second power supply, a third buried power supply line formed in the buried power supply wiring layer and connected to the third power supply, a first line formed in a first wiring layer above the buried power supply wiring layer and connected to the first terminal and the first buried power supply line, and a first via exposed from the back surface and connected to the third buried power supply line. The second semiconductor chip includes a second line connected to the first via.

According to the present disclosure, the first terminal connected to the first power supply for supplying the first power supply voltage is provided on the main surface of the first semiconductor chip. The first terminal is connected to the power switch circuit through the first line of the first wiring layer and the first buried power supply line of the buried power supply wiring layer in the first semiconductor chip. With this configuration, the first power supply voltage can be supplied to the power switch circuit from the first terminal provided on the main surface of the first semiconductor chip; therefore, the present device can be applied even to the case where providing of an external terminal on the first semiconductor chip is defined.

According to the present disclosure, the semiconductor integrated circuit device can be applied to the case where providing of an external terminal on a first semiconductor chip is defined.

### BRIEF DESCRIPTION OF THE DRAWINGS

FIG. 1 is a sectional view of the outline of a semiconductor integrated circuit device according to a first embodiment.

FIG. 2 is a plan view of an example of a layout structure of a first semiconductor chip according to the first embodiment.

FIG. 3 is a circuit diagram of a configuration of a power switch circuit included in the first semiconductor chip according to the first embodiment.

FIG. 4 is a circuit diagram illustrating a configuration of a buffer of a power switch control circuit according to the first embodiment.

FIG. 5 is a plan view of an example of a layout structure of a standard cell region according to the first embodiment.

FIG. 6A shows sectional views of an example of the layout structure of the standard cell region according to the first embodiment.

FIG. 6B is a sectional view of the example of the layout structure of the standard cell region according to the first embodiment.

FIG. 7 is a plan view of another example of the layout structure of the standard cell region according to the first embodiment.

FIG. 8 is a sectional view of the other example of the layout structure of the standard cell region according to the first embodiment.

FIG. 9 is a plan view of still another example of the layout structure of the standard cell region according to the first embodiment.

FIG. 10 is a sectional view of the other example of the layout structure of the standard cell region according to the first embodiment.

FIG. 11 is a plan view of an example of a layout structure of a standard cell region of a first semiconductor chip according to a second embodiment.

FIG. 12 is a plan view of an example of a layout structure of a standard cell region of a second semiconductor chip according to the second embodiment.

FIG. 13A is a sectional view of the example of the layout structure of the standard cell region according to the second embodiment.

FIG. 13B is a sectional view of the example of the layout structure of the standard cell region according to the second embodiment.

FIG. 14 is a plan view of another example of the layout structure of the standard cell region according to the second embodiment.

FIG. 15 is a plan view of still another example of the layout structure of the standard cell region according to the second embodiment.

### DETAILED DESCRIPTION

Embodiments will be described below with reference to the drawings. In the specification and the drawings, components having the substantially same functional configurations are denoted by the same reference numerals, and overlapping description thereof may be omitted. In the following description, two directions parallel to a substrate surface and orthogonal to each other will be referred to as an X direction (first direction) and a Y direction (second direction), and a direction perpendicular to the substrate surface will be referred to as a Z direction. In addition, coincidence of arrangement in the present disclosure does not strictly exclude the case where the arrangement does not coincide due to variation in manufacturing, and even in the case where the arrangement is shifted due to the variation in manufacturing, the arrangement can be regarded as coinciding.

### First Embodiment

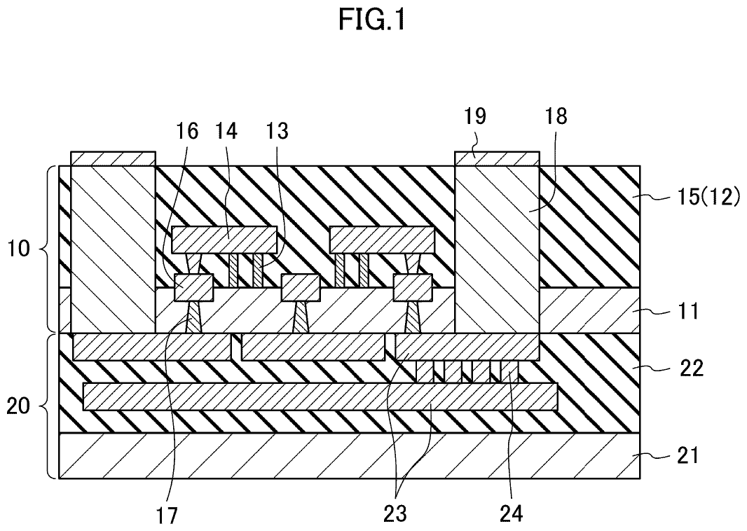

FIG. 1 is a sectional view of a semiconductor integrated circuit device according to a first embodiment.

As illustrated in FIG. 1, the semiconductor integrated circuit device according to the first embodiment includes a first semiconductor chip 10 and a second semiconductor chip 20.

The first semiconductor chip 10 includes a substrate 11 and a wiring layer 12.

The substrate 11 is, for example, a silicon substrate, and a semiconductor element such as a transistor is provided on the front surface side of the substrate 11. The transistor is, for example, a FinFET including fins 13 in a source, a drain, and a channel.

The wiring layer 12 includes lines 14 and an insulating layer 15 provided on the front surface of the substrate 11. Part of each line 14 is connected to the fin 13. Further, a buried power supply line 16 connected to the line 14 is provided on the front surface side of the substrate 11. The buried power supply line 16 is a buried power rail (BPR) of a buried power supply wiring layer formed with at least part thereof buried in the substrate 11.

The substrate 11 is provided with vias 17 connecting the buried power supply lines 16 to the back surface of the substrate 11. Further, the substrate 11 is provided with vias 18 connecting pads 19 to lines 23 formed in the upper surface of a wiring layer 22. Each pad 19 is, for example, an external terminal connected to a wiring substrate or a board. Each via 17, 18 is, for example, a through-silicon via (TSV).

The second semiconductor chip 20 is disposed so as to face the back surface of the substrate 11 of the first semiconductor chip 10. The second semiconductor chip 20 includes a substrate 21 and a wiring layer 22.

The substrate 21 is, for example, a silicon substrate.

The wiring layer 22 is provided on the front surface of the substrate 21. The upper surface of the wiring layer 22 faces the back surface of the substrate 11 of the first semiconductor chip 10. That is, the wiring layer 22 is located between the substrate 11 and the substrate 21.

The wiring layer 22 includes a plurality of lines 23. Part of each line 23 formed in the upper surface of the wiring layer 22 is connected to each buried power supply line 16 through each via 17. The other part of each line 23 formed in the upper surface of the wiring layer 22 is connected to each pad 19 through each via 18. The plurality of lines 23 is partially connected to each other through vias 24.

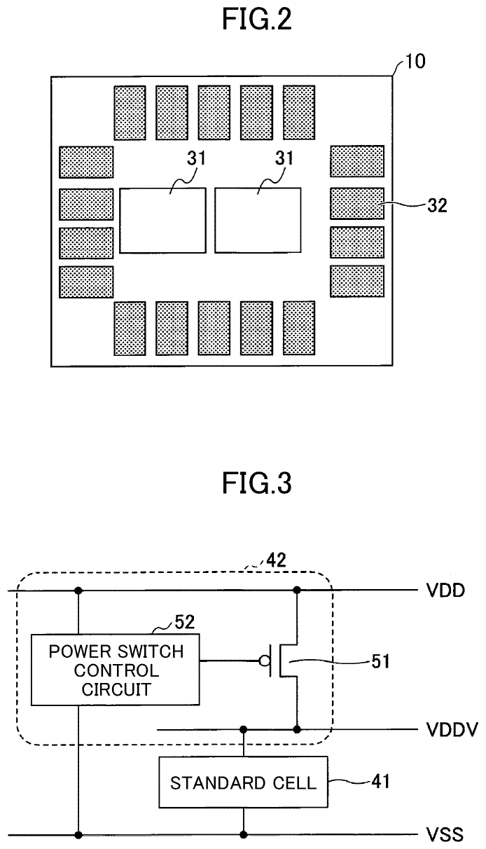

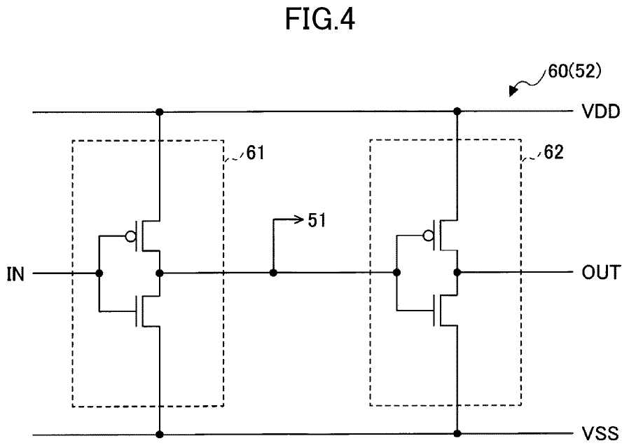

FIG. 2 is a plan view of an example of a layout structure of the first semiconductor chip according to the first embodiment. FIG. 3 is a circuit diagram illustrating the configuration of a power switch circuit included in the first semiconductor chip according to the first embodiment.

As illustrated in FIG. 2, the first semiconductor chip 10 includes a plurality of standard cell regions 31 and a plurality of input/output (I/O) cell regions 32 arranged therearound. The number of standard cell regions 31 to be arranged may be one or three or more.

As illustrated in FIG. 3, the standard cell region 31 includes a standard cell 41 and a power switch circuit 42. The standard cell 41 includes various logic circuits such as a NAND circuit and an inverter circuit. In the standard cell region 31, a VSS line for supplying a ground voltage to the standard cell 41 and a VDDV line for supplying a power supply voltage to the standard cell 41 are arranged. Moreover, in the standard cell region 31, a VDD line for supplying a power supply voltage to the power switch circuit 42 from the outside is disposed.

As illustrated in FIG. 3, the power switch circuit 42 includes a switch transistor 51 and a power switch control circuit 52. The switch transistor 51 is a P-channel MOS transistor, and is connected between the VDD line and the VDDV line. The power switch control circuit 52 is connected to the gate of the switch transistor 51, and controls operation of the switch transistor 51. The power switch control circuit 52 switches ON/OFF of the switch transistor 51 to control conduction between the VDD line and the VDDV line. The power switch control circuit 52 is, for example, a buffer.

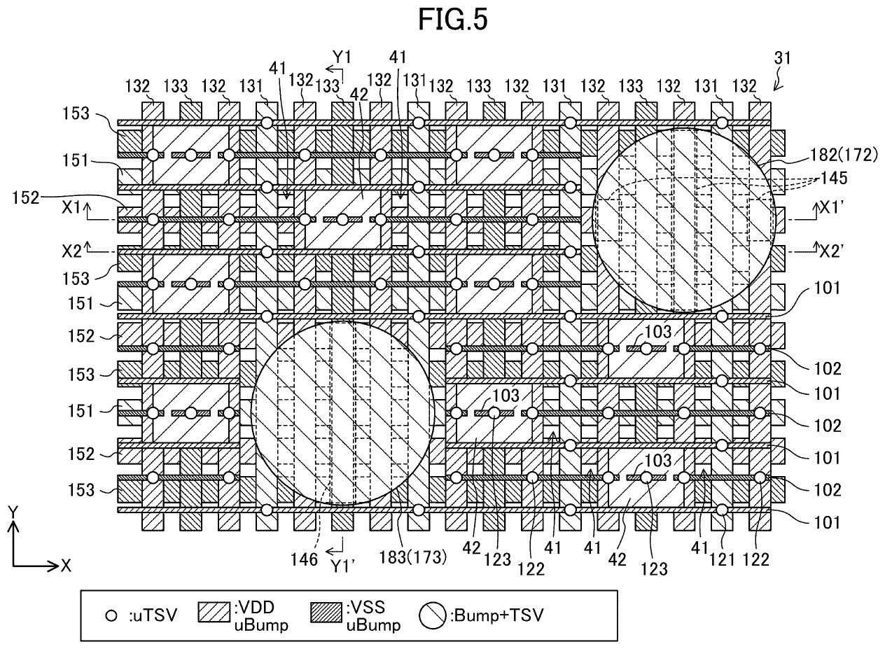

FIG. 4 is a circuit diagram illustrating the configuration of the buffer of the power switch control circuit according to the first embodiment.

As illustrated in FIG. 4, a buffer 60 used in the power switch control circuit 52 includes an inverter 61 and an inverter 62. An input signal IN is input to the inverter 61, the output of the inverter 61 is input to the gate of the switch transistor 51 and the inverter 62, and an output signal OUT is output from the inverter 62. Each of the inverters 61, 62 includes a pair of a P-channel MOS transistor and an N-channel MOS transistor.

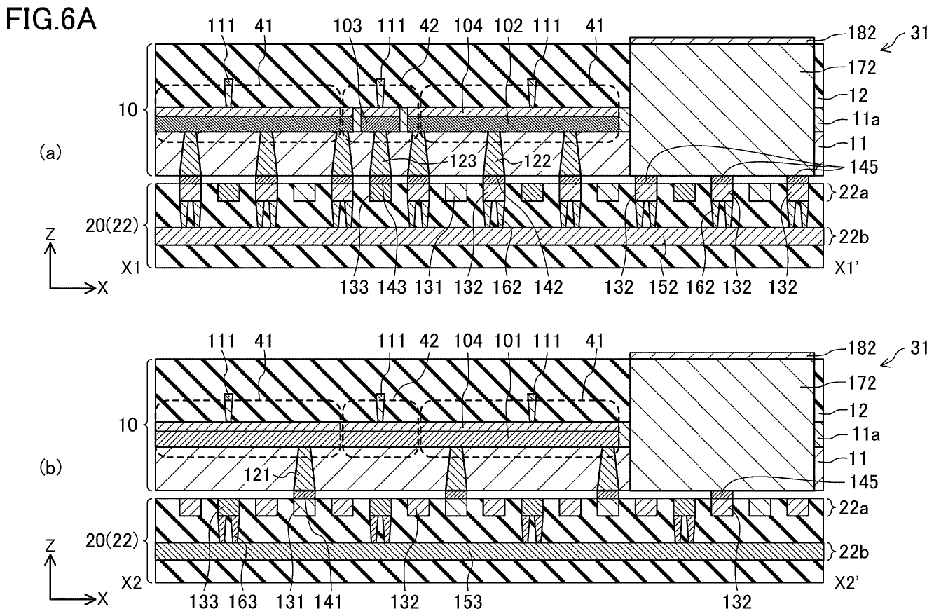

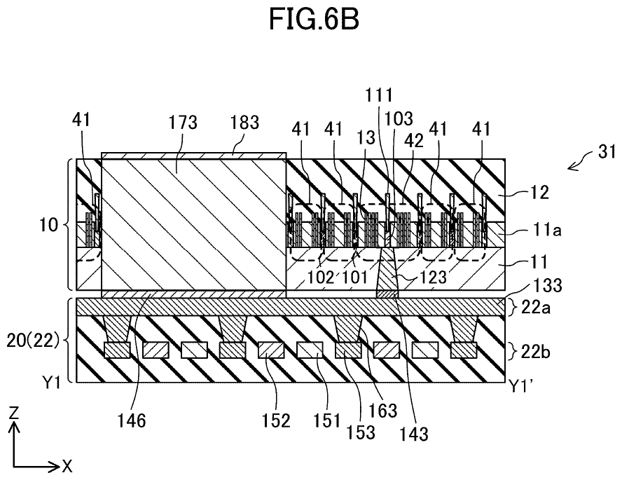

FIG. 5 is a plan view of an example of a layout structure of the standard cell region according to the first embodiment. FIGS. 6A and 6B are sectional views of the example of the layout structure of the standard cell region according to the first embodiment. Specifically, (a) of FIG. 6A illustrates a section taken along line X1-X1′, (b) of FIG. 6A illustrates a section taken along line X2-X2′, and FIG. 6B illustrates a section taken along line Y1-Y1′.

As illustrated in FIGS. 5, 6A, and 6B, a plurality of standard cells 41 and a plurality of power switch circuits 42 are arranged in the standard cell region 31.

As illustrated in FIG. 5, in the standard cell region 31, a plurality of buried power supply lines 101, 102 extending in the X direction are alternately arranged in the Y direction. The power switch circuit 42 further includes a buried power supply line 103 extending in the X direction. The buried power supply line 103 is disposed between the buried power supply lines 101 adjacent to each other in the Y direction, and is disposed such that the position thereof in the Y direction coincides with the buried power supply line 102. The buried power supply line 101 is equivalent to the VDDV line, the buried power supply line 102 is equivalent to the VSS line, and the buried power supply line 103 is equivalent to the VDD line. The buried power supply lines 101 to 103 are part of the buried power supply line 16.

As illustrated in FIG. 6B, the standard cell 41 and the power switch circuit 42 include the FinFET having the fin 13.

As illustrated in FIGS. 6A and 6B, a device isolation film 11a is provided on the front surface of the substrate 11. The device isolation film 11a is formed by, for example, a shallow trench isolation (STI) method. A plurality of grooves extending in the X direction is formed in the substrate 11 and the device isolation film 11a. The buried power supply lines 101 to 103 are formed in these grooves. The front surfaces of the buried power supply lines 101 to 103 are covered with an insulating film 104. In this manner, the buried power supply lines 101 to 103 are formed in the buried power supply wiring layer in the first semiconductor chip 10. The front surface of the device isolation film 11a and the front surface of the insulating film 104 may or may not be flush with the front surface of the substrate 11.

A local line 111 is formed in a layer above the buried power supply lines 101 to 103. Part of the local line 111 is connected to the buried power supply lines 101 to 103. Although not illustrated in the figure, part of the local line 111 is connected to the fin 13. The local line 111 is part of the line 14.

Vias 121 to 123 penetrating the substrate 11 in the Z direction are formed in the substrate 11. The via 121 is formed below the buried power supply line 101, the via 122 is formed below the buried power supply line 102, and the via 123 is formed below the buried power supply line 103. The vias 121 to 123 are parts of the vias 17.

As illustrated in FIGS. 5, 6A, and 6B, in an upper wiring layer 22a of the wiring layer 22 of the second semiconductor chip 20, lines 131 to 133 extending in the Y direction are arranged in the X direction. The upper surfaces of the lines 131 to 133 are exposed from the wiring layer 22. The lines 131 to 133 are connected to the respective vias 121 to 123 through bumps 141 to 143.

In a lower wiring layer 22b of the wiring layer 22 of the second semiconductor chip 20, lines 151 to 153 extending in the X direction are arranged in the Y direction. The lines 131 to 133, 151 to 153 are part of the line 23.

Vias 162, 163 are formed between the upper wiring layer 22a and the lower wiring layer 22b. The lines 132, 133 are connected to the respective lines 152, 153 through the vias 162, 163. The vias 162, 163 are parts of the vias 24. Although not illustrated in the figure, a via for connecting the line 131 and the line 151 is formed between the upper wiring layer 22a and the lower wiring layer 22b.

In the first semiconductor chip 10, vias 172, 173 are formed so as to penetrate the wiring layer 12 and the substrate 11 from the upper surface of the wiring layer 12 to the back surface of the substrate 11. The vias 172, 173 are parts of the vias 18. The vias 172, 173 are connected to the respective lines 132, 133 through bumps 145, 146. The bumps 141 to 145 are, for example, solder microbumps.

The vias 172, 173 are connected to the pad 19 through bumps 182, 183. Although not illustrated in the figure, the pads 19 are connected to power supplies provided outside the semiconductor integrated circuit device to supply power supply voltages VDD, VSS. In FIGS. 5 and 6, the power supply for supplying the power supply voltage VDD is connected to the pad 19 to which the via 173 is connected, and the power supply for supplying the power supply voltage VSS is connected to the pad 19 to which the via 172 is connected.

That is, the power supply voltage VDD is supplied to the power switch circuit 42 through the bump 183, the via 173, the bump 146, the line 133, the bump 143, the via 123, and the buried power supply line 103. Moreover, the power supply voltage VSS is supplied to the standard cell 41 and the power switch circuit 42 through the bump 182, the via 172, the bump 145, the line 132, the bump 142, the via 122, and the buried power supply line 102.

As illustrated in FIG. 5, the vias 172, 173 are arranged at positions at which the standard cells 41 and the power switch circuits 42 are not arranged in a plan view.

With the above-described configuration, the first semiconductor chip 10 includes the pad 19 provided on the wiring layer 12 and connected to the power supply for supplying the power supply voltage VDD, the pad 19 provided on the wiring layer 12 and connected to the power supply for supplying the power supply voltage VSS, the power switch circuit 42 provided between the VDD line and the VDDV line to control connection and disconnection between the VDD line and the VDDV line, the buried power supply line 103 formed in the buried power supply wiring layer and connected to the power supply for supplying the power supply voltage VDD, the buried power supply line 102 formed in the buried power supply wiring layer and connected to the power supply for supplying the power supply voltage VSS, and the via 172 connected to the pad 19 connected to the power supply for supplying the power supply voltage VSS and provided so as to penetrate the substrate 11 and the wiring layer 12. The second semiconductor chip 20 includes the lines 132 connected to the buried power supply line 102 and the via 172.

That is, the pad 19 connected to the power supply for supplying the power supply voltage VSS is provided on the wiring layer 12 of the first semiconductor chip 10. This pad 19 is connected to the power switch circuit 42 through the via 172 penetrating the substrate 11 and the wiring layer 12, the line 132 of the second semiconductor chip 20, and the buried power supply line 102 of the first semiconductor chip 10. With this configuration, the power supply voltage VSS can be supplied to the power switch circuit 42 from the pad 19 provided on the wiring layer 12 of the first semiconductor chip 10; therefore, the present device can be applied even to the case where providing of an external terminal on the first semiconductor chip 10 is defined.

The power supply voltages VDD, VSS supplied to the standard cell 41 and the power switch circuit 42 through the vias 173, 172 are supplied to the second semiconductor chip 20, and thereafter are supplied to the first semiconductor chip 10. With this configuration, the power supply voltage can be stably supplied to the second semiconductor chip 20; therefore, a drop in the power supply voltage supplied to the standard cell 41 and the power switch circuit 42 can be suppressed and power supply noise can be reduced.

Further, the buried power supply lines 101 to 103 extending in the X direction in the first semiconductor chip 10 are connected to the respective lines 131 to 133 extending in the Y direction in the second semiconductor chip 20. In the second semiconductor chip 20, the lines 131 to 133 are connected to the respective lines 151 to 153 extending in the X direction. With this configuration, a mesh-like power delivery network for supplying the power supply voltages VDDV, VSS, VDD is formed; therefore, it is possible to suppress a drop in the power supply voltage supplied to the standard cell 41 and the power switch circuit 42 and to reduce power supply noise.

The lines 131 to 133, 151 to 153 are provided in the second semiconductor chip 20. This eliminates the need to form a power delivery network in the first semiconductor chip 10; therefore, the degree of freedom in the arrangement of the lines in the first semiconductor chip is improved.

The buried power supply lines 101 to 103 are formed in the buried power supply wiring layer. This eliminates the need to provide a power supply line in the wiring layer 12; therefore, the degree of freedom in the arrangement of the lines in the wiring layer 12 of the first semiconductor chip 10 is improved.

The bumps 141 to 145 are, for example, the solder microbumps, but are not limited thereto. For example, the lines 131 to 133 and the vias 121 to 123 may be connected by, e.g., a metal film made of tin (Sn). That is, any configuration may be employed as long as the lines 131 to 133 and the vias 121 to 123 are connected to each other.

### (Variation 1)

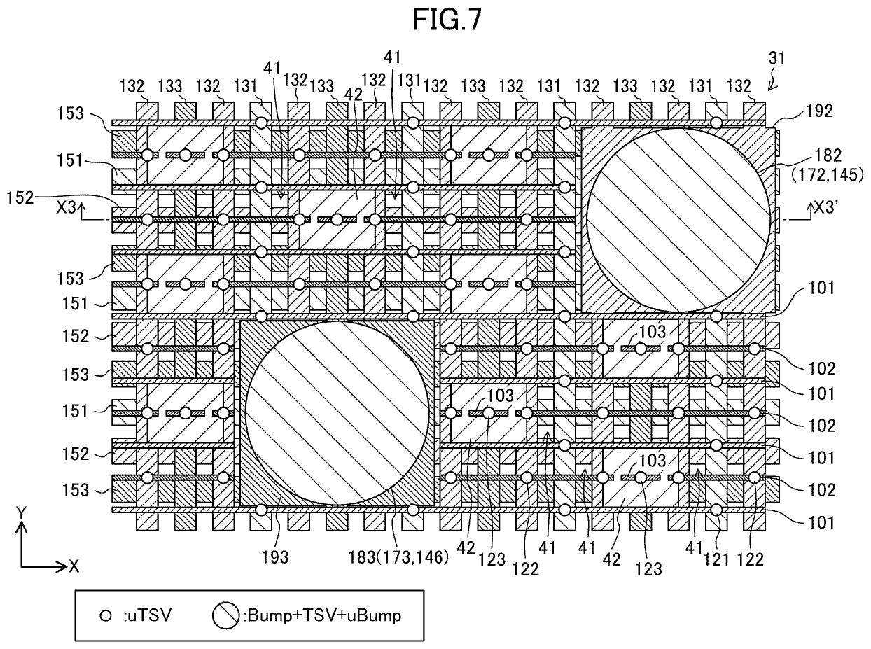

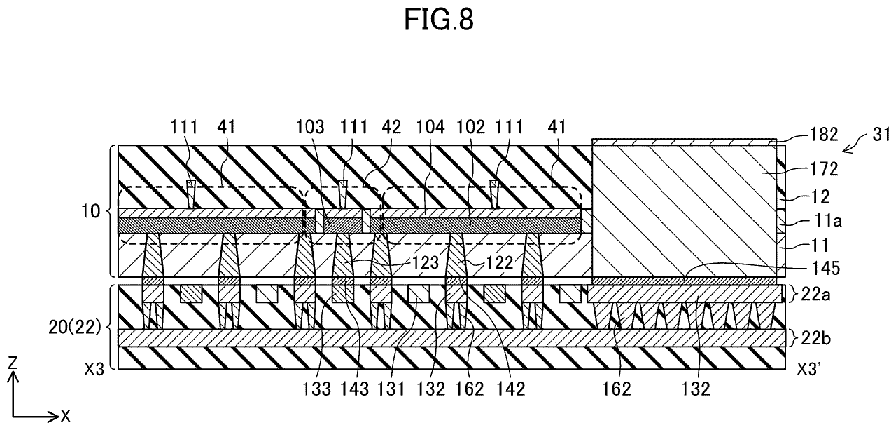

FIG. 7 is a plan view of another example of the layout structure of the standard cell region according to the first embodiment. FIG. 8 is a sectional view of the other example of the layout structure of the standard cell region according to the first embodiment. Specifically, FIG. 8 illustrates a section taken along line X3-X3′.

In FIG. 7, as compared to FIG. 5, connection portions 192, 193 are formed below the respective vias 172, 173.

As illustrated in FIGS. 7 and 8, the connection portions 192, 193 are formed in the upper wiring layer 22a of the wiring layer 22. Each of the connection portions 192, 193 is formed in a flat plate shape in a plan view.

The connection portion 192 connects a plurality (three in FIG. 7) of lines 132 adjacent to each other. The connection portion 192 has greater widths in the X direction and the Y direction than the widths of the via 172 (bump 182) in the X direction and the Y direction in a plan view. The bumps 145, 182 are formed in the same shape (circle in FIG. 7) in a plan view. The connection portion 192 is not connected to the lines 131, 133.

The connection portion 193 is connected to the line 133. The connection portion 193 has greater widths in the X direction and the Y direction than the widths of the via 173 (bump 183) in the X direction and the Y direction in a plan view. The bumps 146, 183 are formed in the same shape (circle in FIG. 7) in a plan view. The connection portion 193 is not connected to the lines 131, 132.

In the present variation, the bump 145 and the via 172 have the same shape in a plan view and the bump 146 and the via 173 have the same shape in a plan view; therefore, a resistance value between the bump 182 of the first semiconductor chip 10 and the line 132 of the second semiconductor chip 20 and a resistance value between the bump 183 of the first semiconductor chip 10 and the line 133 of the second semiconductor chip 20 can be reduced. Thus, the power supply voltage can be stably supplied to the lines 132, 133 of the second semiconductor chip 20.

In addition, advantages similar to those of FIG. 5 can be obtained.

Each of the connection portions 192, 193 is formed in the flat plate shape, but the present disclosure is not limited thereto. For example, each of the connection portions 192, 193 may include a plurality of strip-like lines, or may be formed in a grid shape. That is, the connection portions 192, 193 may include a region where a slit is partially formed and a line is not formed.

### (Variation 2)

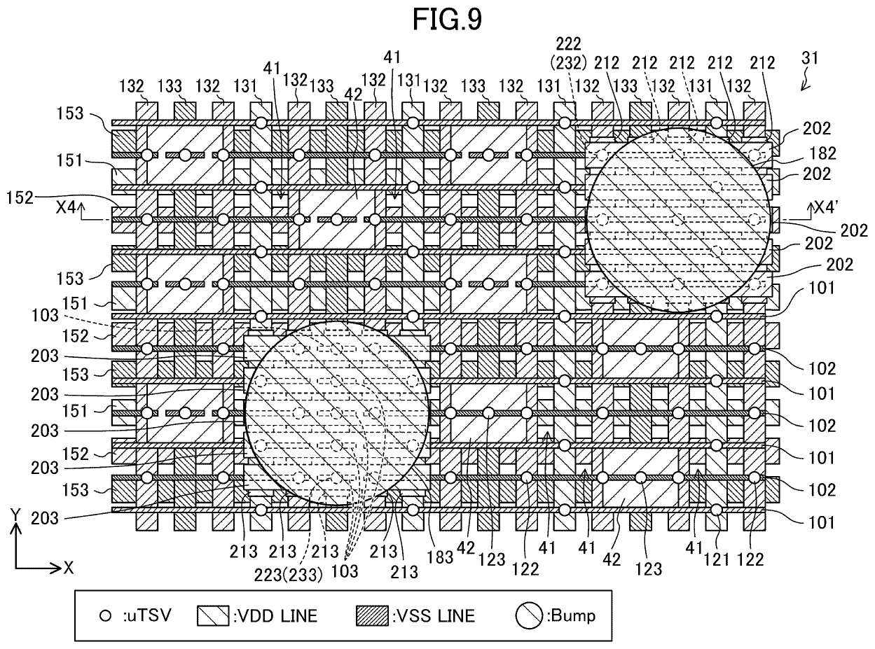

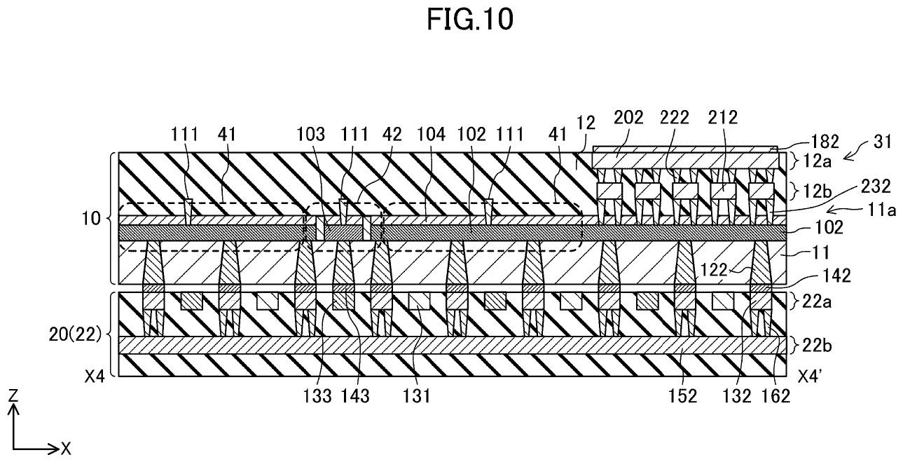

FIG. 9 is a plan view of still another example of the layout structure of the standard cell region according to the first embodiment. FIG. 10 is a sectional view of the other example of the layout structure of the standard cell region according to the first embodiment. Specifically, FIG. 10 illustrates a section taken along line X4-X4′. In FIG. 9, as compared to FIG. 5, a plurality of lines and a plurality of vias are arranged in the wiring layer 12 of the first semiconductor chip 10 instead of the vias 172, 173.

As illustrated in FIGS. 9 and 10, a plurality of lines 202 and a plurality of lines 203 extending in the X direction are formed in an upper wiring layer 12a of the wiring layer 12 of the first semiconductor chip 10. The upper surfaces of the lines 202, 203 are exposed from the wiring layer 12, and are connected to the respective bumps 182, 183. A plurality of lines 212 and a plurality of lines 213 extending in the Y direction are formed in a lower wiring layer 12b of the wiring layer 12 of the first semiconductor chip 10. The lines 202, 212 are formed below the bump 182, and the lines 203, 213 are formed below the bump 183. Parts of the lines 202, 203, 212, 213 overlaps with the buried power supply lines 101, 102 in a plan view.

A plurality of vias 222, 223 is formed below the lines 202, 203. The lines 202, 203 are connected to the respective lines 212, 213 through the vias 222, 223. A plurality of vias 232, 233 is formed below the lines 212, 213. The lines 212, 213 are connected to the buried power supply lines 102, 103 through the vias 232,233.

A plurality (five in this case) of buried power supply lines 103 is formed below the line 213. The plurality of buried power supply lines 103 is arranged between the buried power supply lines 101 (or the buried power supply lines 102) arranged in the X direction.

That is, the power supply voltage VDD is supplied to the power switch circuit 42 through the bump 183, the line 203, the via 223, the line 213, the via 233, and the buried power supply line 103. Moreover, the power supply voltage VSS is supplied to the standard cell 41 and the power switch circuit 42 through the bump 182, the line 202, the via 222, the line 212, the via 232, and the buried power supply line 102.

In this variation, unlike FIG. 5, the buried power supply lines 101, 102 extending in the X direction are continuously formed below the bumps 182, 183; therefore, the power supply voltage supplied to the first semiconductor chip 10 is strengthened.

It is not necessary to form the vias 172, 173 penetrating the wiring layer 12 and the substrate 11 in the first semiconductor chip 10; therefore, it is not necessary to form two types of TSVs (vias 121 to 123 and vias 172, 173) having different lengths in the Z direction. This improves the manufacturability of the semiconductor integrated circuit device, and therefore improves the yield and reliability of the semiconductor integrated circuit device.

In addition, advantages similar to those of FIG. 5 can be obtained.

In this variation, the two wiring layers (upper wiring layer 12a and lower wiring layer 12b) are formed in the wiring layer 12 of the first semiconductor chip 10, and the power supply voltage is supplied to the standard cell 41 and the power switch circuit 42 through these wiring layers. However, the present disclosure is not limited thereto. The number of wiring layers through which the power supply voltage is supplied to the standard cell 41 and the power switch circuit 42 may be one or three or more.

### Second Embodiment

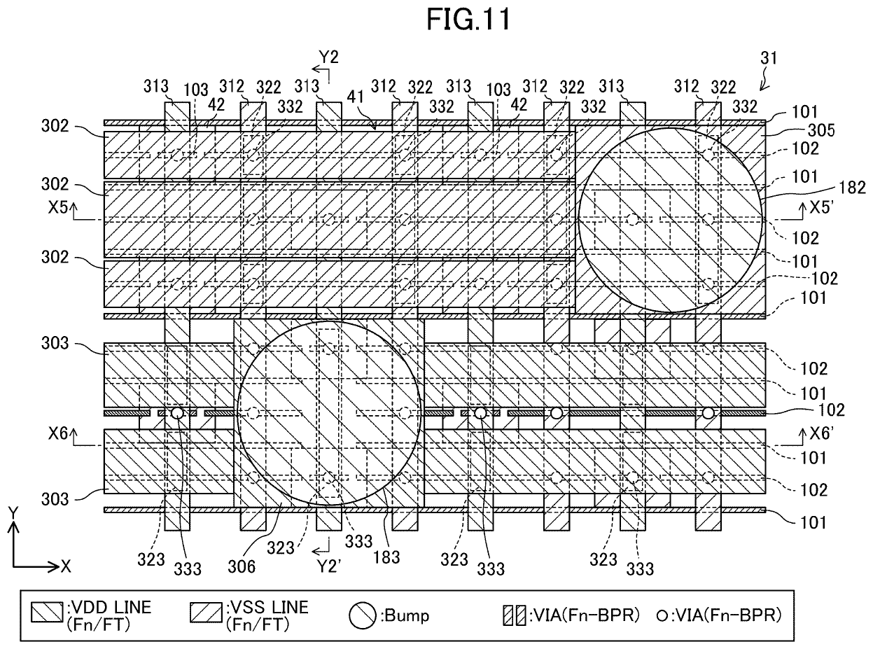

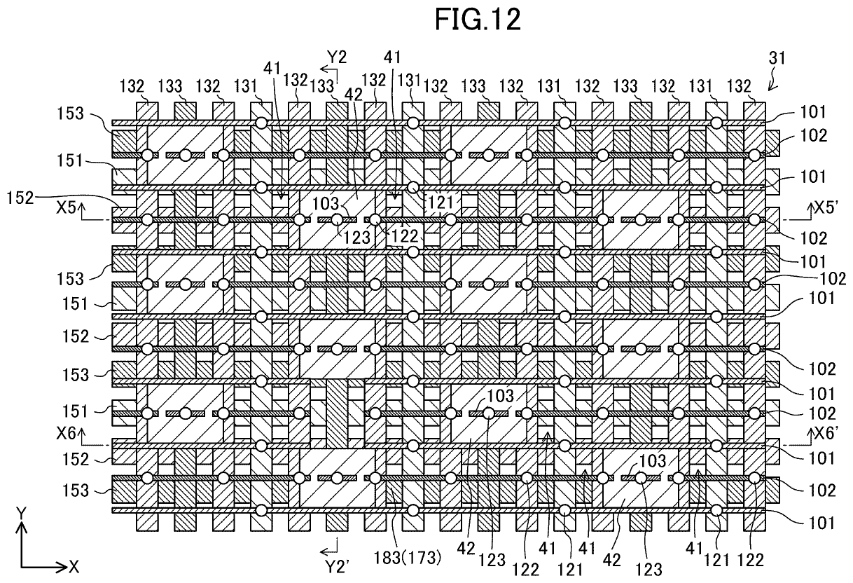

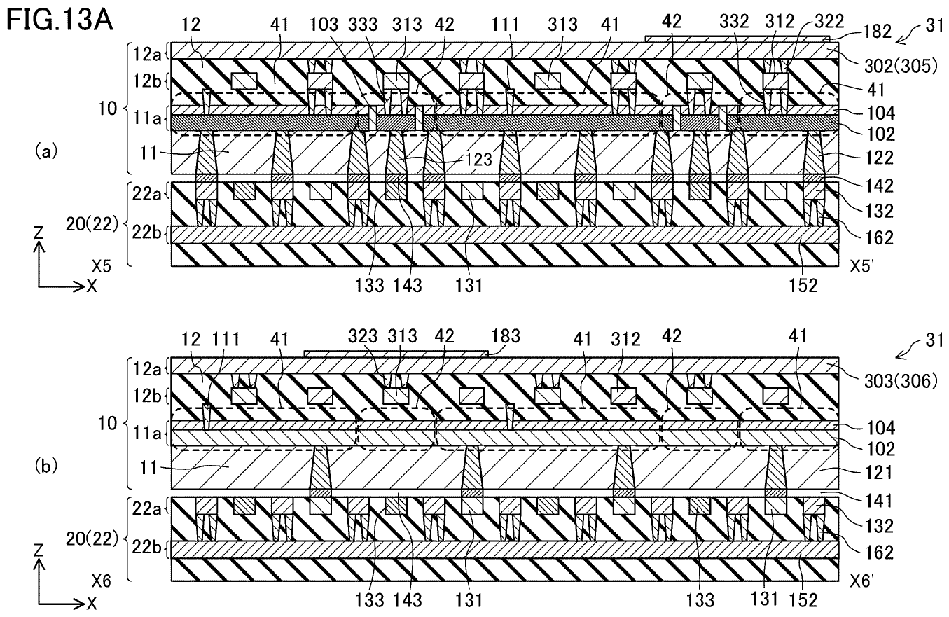

FIG. 11 is a plan view of an example of a layout structure of a standard cell region of a first semiconductor chip according to a second embodiment, FIG. 12 is a plan view of an example of a layout structure of a standard cell region of a second semiconductor chip according to the second embodiment, and FIGS. 13A and 13B are sectional views of an example of a standard cell region in a semiconductor circuit device according to the second embodiment. Specifically, (a) of FIG. 13A illustrates a section taken along line X5-X5′, (b) of FIG. 13A illustrates a section taken along line X6-X6′, and FIG. 13B illustrates a section taken along line Y2-Y2′.

As illustrated in FIGS. 11, 12, 13A, and 13B, a plurality of lines 302, 303 extending in the X direction is formed in an upper wiring layer 12a of a wiring layer 12 of a first semiconductor chip 10. The plurality (three in this case) of lines 302 is connected by a connection portion 305. The plurality (two in this case) of lines 303 is connected by a connection portion 306. Upper portions of the connection portions 305, 306 are exposed from the wiring layer 12, and are each connected to bumps 182, 183. In a lower wiring layer 12b of the wiring layer 12 of the first semiconductor chip 10, a plurality of lines 312, 313 extending in the Y direction is alternately arranged in the X direction. Parts of the lines 302, 303, 312, 313 overlap with buried power supply lines 101, 102 in a plan view. Moreover, the lines 302, 303, 312, 313 partially overlap with a standard cell 41 and a power switch circuit 42 in a plan view.

A plurality of vias 322 is formed below the line 302 and the connection portion 305, and a plurality of vias 323 is formed below the line 303 and the connection portion 306. The line 302 and the connection portion 305 are connected to the line 312 through the via 322. The line 303 and the connection portion 306 are connected to the line 313 through the via 323.

A plurality of vias 332, 333 is formed below the lines 312, 313. The lines 312, 313 are each connected to the buried power supply lines 102, 103 through the vias 332, 333.

That is, a power supply voltage VDD is supplied to the power switch circuit 42 through the bump 183, the line 303 (connection portion 306), the via 323, the line 313, the via 333, and the buried power supply line 103. Moreover, a power supply voltage VSS is supplied to the standard cell 41 and the power switch circuit 42 through the bump 182, the line 302 (connection portion 305), the via 322, the line 312, the via 332, and the buried power supply line 102.

With the above-described configuration, the first semiconductor chip 10 includes a pad 19 provided on the wiring layer 12 and connected to a power supply for supplying the power supply voltage VDD, a pad 19 provided on the wiring layer 12 and connected to a power supply for supplying the power supply voltage VSS, the power switch circuit 42 provided between a VDD line and a VDDV line to control connection and disconnection between the VDD line and the VDDV line, the buried power supply line 103 formed in a buried power supply wiring layer and connected to the power supply for supplying the power supply voltage VDD, the buried power supply line 102 formed in the buried power supply wiring layer and connected to the power supply for supplying the power supply voltage VSS, the buried power supply line 101 formed in the buried power supply wiring layer and connected to a power supply for supplying a power supply voltage VDDV, the lines 302, 312 each formed in the upper wiring layer 12a and the lower wiring layer 12b above the buried power supply wiring layer and connected to the pad 19 and the buried power supply line 102 connected to the power supply for supplying the power supply voltage VSS, and a via 121 having an exposed back surface and connected to the buried power supply line 101. A second semiconductor chip 20 includes a line 131 connected to the via 121.

That is, the pad 19 connected to the power supply for supplying the power supply voltage VSS is provided on the wiring layer 12 of the first semiconductor chip 10. This pad 19 is connected to the power switch circuit 42 through the line 302 of the upper wiring layer 12a, the line 312 of the lower wiring layer 12b, and the buried power supply line 102 of the first semiconductor chip 10. With this configuration, the power supply voltage VSS can be supplied to the power switch circuit 42 from the pad 19 provided on the wiring layer 12 of the first semiconductor chip 10; therefore, the present device can be applied even to the case where providing of an external terminal on the first semiconductor chip 10 is defined.

In this embodiment, unlike FIG. 5, the buried power supply lines 101, 102 extending in the X direction are continuously formed below the bumps 182, 183; therefore, the power for the first semiconductor chip 10 is strengthened.

The standard cell 41 and the power switch circuit 42 can be arranged below the bumps 182, 183; therefore, the area of the semiconductor integrated circuit device can be reduced.

It is not necessary to form vias 172, 173 penetrating the wiring layer 12 and a substrate 11 in the first semiconductor chip 10; therefore, it is not necessary to form two types of TSVs (vias 121 to 123 and vias 172, 173) having different lengths in the Z direction. This improves the manufacturability of the semiconductor integrated circuit device, and therefore improves the yield and reliability of the semiconductor integrated circuit device.

### (Variation 1)

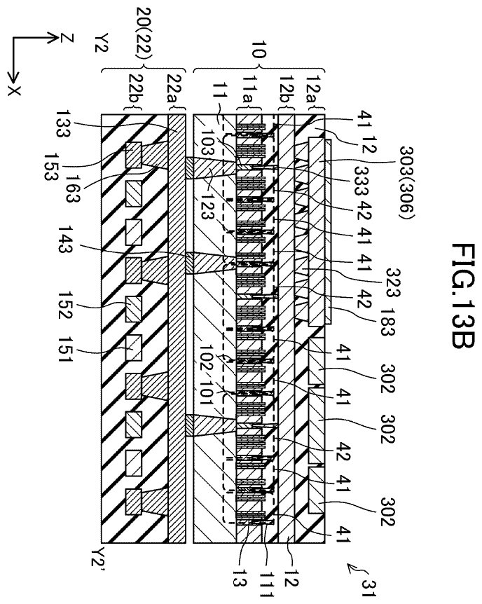

FIG. 14 is a plan view of another example of the layout structure of the standard cell region according to the second embodiment. Specifically, FIG. 14 illustrates a plan view of a standard cell region 31 from the buried power supply wiring layer of the first semiconductor chip 10 to the second semiconductor chip 20. In FIG. 14, the lines 133, 153 in the wiring layer 22 of the second semiconductor chip 20 are omitted as compared to FIGS. 11 and 12. FIG. 14 illustrates a VDD line 310 formed in the wiring layer 12 of the first semiconductor chip 10. The power supply voltage VDD is supplied to the power switch circuit 42 through the VDD line 310.

As illustrated in FIG. 14, a power delivery network (lines 131, 151, 132, 152) for supplying the power supply voltages VDDV, VSS to the standard cell 41 and the power switch circuit 42 is formed in the second semiconductor chip 20. This makes it possible to strengthen the power supply voltages VDDV, VSS supplied to the standard cell 41 and the power switch circuit 42. A power delivery network for supplying the power supply voltage VDD to the standard cell 41 and the power switch circuit 42 is provided only in the first semiconductor chip (see, e.g., FIG. 11).

The buried power supply lines 101, 102 extending in the X direction are continuously formed below the bumps 182, 183; therefore, the power supply voltage supplied to the first semiconductor chip 10 is strengthened.

In addition, advantages similar to those of FIGS. 11 and 12 can be obtained.

### (Variation 2)

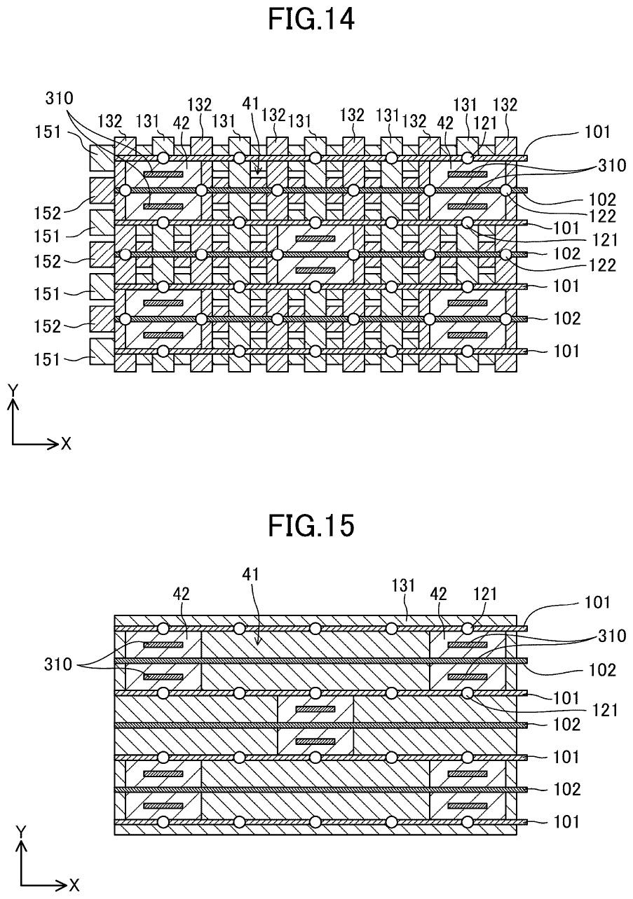

FIG. 15 is a plan view of another example of the layout structure of the standard cell region according to the second embodiment. Specifically, FIG. 15 illustrates a plan view of the standard cell region 31 from the buried power supply wiring layer of the first semiconductor chip 10 to the second semiconductor chip 20. In FIG. 15, as compared to FIG. 14, only the line 131 is formed in the wiring layer 22 of the second semiconductor chip 20.

Specifically, the wiring layer 22 of the second semiconductor chip 20 is provided with the plate-like line 131 extending in the X direction and the Y direction. The buried power supply line 101 is connected to the line 131 through the via 121 (and a bump 141). This makes it possible to strengthen the power supply voltage VDDV supplied to the power switch circuit 42.

In addition, advantages similar to those of FIG. 14 can be obtained.

The line 131 is formed in the flat plate shape, but the present disclosure is not limited thereto. For example, the line 131 may include a plurality of strip-like lines, or may be formed in a grid shape. That is, the line 131 may include a region where a slit is partially formed and a line is not formed.

In each of the embodiments and variations above, the planar shape of the via is not particularly limited, and may be, for example, a circle, an ellipse, a square, or a rectangle.

In each of the embodiments and variations above, the second semiconductor chip 20 does not necessarily include the substrate 21.

The present disclosure can also be applied to the case where providing of an external terminal on a first semiconductor chip is defined.

What is claimed is:

1. A semiconductor integrated circuit device including: a first semiconductor chip; and a second semiconductor chip,
a back surface of the first semiconductor chip and a main surface of the second semiconductor chip being arranged so as to face each other,
the first semiconductor chip including:
a first terminal provided on the main surface and connected to a first power supply for supplying a first power supply voltage;
a second terminal provided on the main surface and connected to a second power supply for supplying a second power supply voltage different from the first power supply voltage;
a power switch circuit provided between the first power supply and a third power supply to control connection and disconnection between the first power supply and the third power supply,
a first buried power supply line formed in a buried power supply wiring layer and connected to the first power supply,
a second buried power supply line formed in the buried power supply wiring layer and connected to the second power supply, and
a first via connected to the first terminal and provided so as to penetrate from the main surface to the back surface,
the second semiconductor chip including a first line connected to the first buried power supply line and the first via.

2. The semiconductor integrated circuit device of claim 1, wherein
the first semiconductor chip further includes: a second via connected to the second terminal and provided so as to penetrate from the main surface to the back surface, and
the second semiconductor chip further includes: a second line connected to the second buried power supply line and the second via.

3. The semiconductor integrated circuit device of claim 1, wherein
the first semiconductor chip further includes a third via exposed from the back surface and connected to the first buried power supply line and the first line.

4. The semiconductor integrated circuit device of claim 1, wherein
the first line of the second semiconductor chip includes a plurality of first lines,
the plurality of first lines is connected through a connection portion formed in a flat plate shape, and
the connection portion is connected to the first via.

5. The semiconductor integrated circuit device of claim 4, wherein
the first buried power supply line and the second buried power supply line extend in a first direction, and
a width of the connection portion in the first direction is greater than a width of the first via in the first direction.

6. A semiconductor integrated circuit device including: a first semiconductor chip; and a second semiconductor chip,
a back surface of the first semiconductor chip and a main surface of the second semiconductor chip being arranged so as to face each other,
the first semiconductor chip including:
a first terminal provided on the main surface and connected to a first power supply for supplying a first power supply voltage;
a second terminal provided on the main surface and connected to a second power supply for supplying a second power supply voltage different from the first power supply voltage;
a power switch circuit provided between the first power supply and a third power supply to control connection and disconnection between the first power supply and the third power supply;
a first buried power supply line formed in a buried power supply wiring layer and connected to the first power supply;
a second buried power supply line formed in the buried power supply wiring layer and connected to the second power supply; and
a first line formed in a first wiring layer above the buried power supply wiring layer and connected to the first terminal and the first buried power supply line,
the second semiconductor chip including a second line connected to the first buried power supply line.

7. The semiconductor integrated circuit device of claim 6, wherein
the first semiconductor chip further includes a third line formed in the first wiring layer and connected to the second terminal and the second buried power supply line, and
the second semiconductor chip further includes a fourth line connected to the second buried power supply line and the third line.

8. The semiconductor integrated circuit device of claim 6, wherein
the first line overlaps with at least one of the first buried power supply line or the second buried power supply line in a plan view.

9. The semiconductor integrated circuit device of claim 6, wherein
the first semiconductor chip further includes a second via exposed from the back surface and connected to the first buried power supply line and the first line.

10. A semiconductor integrated circuit device including: a first semiconductor chip; and a second semiconductor chip,
a back surface of the first semiconductor chip and a main surface of the second semiconductor chip being arranged so as to face each other,
the first semiconductor chip including:
a first terminal provided on the main surface and connected to a first power supply for supplying a first power supply voltage;
a second terminal provided on the main surface and connected to a second power supply for supplying a second power supply voltage different from the first power supply voltage;
a power switch circuit provided between the first power supply and a third power supply to control connection and disconnection between the first power supply and the third power supply;
a second buried power supply line formed in a buried power supply wiring layer and connected to the second power supply;
a third buried power supply line formed in the buried power supply wiring layer and connected to the third power supply;
a first line formed in a first wiring layer above the buried power supply wiring layer and connected to the first terminal; and
a first via exposed from the back surface and connected to the third buried power supply line,
the second semiconductor chip including a second line connected to the first via.

11. The semiconductor integrated circuit device of claim 10, wherein
the first semiconductor chip further includes a third line formed in the first wiring layer and connected to the second terminal and the second buried power supply line.

12. The semiconductor integrated circuit device of claim 10, wherein
the first line overlaps with the power switch circuit in a plan view.

13. The semiconductor integrated circuit device of claim 10, wherein
the first line overlaps with at least one of the first or second buried power supply line in a plan view.

14. The semiconductor integrated circuit device of claim 10, wherein
the second semiconductor chip further includes a fourth line formed in a wiring layer below the second line and extending in a first direction, and
the second line extends in a second direction different from the first direction, and is connected to the fourth line.

15. The semiconductor integrated circuit device of claim 10, wherein
the second line is formed in a flat plate shape.
